(19) United States
(12) Patent Application Publication
(10) Pub. No.: US 2003/0185074 A1
(43) Pub. Date: Oct. 2, 2003

(54) Semiconductor memory device, method for testing same and semiconductor device

(76) Inventor: Masatsugu Nakamura, Kanagawa (JP)

Correspondence Address: WHITHAM, CURTIS & CHRISTOFFERSON, P.C., 11491 SUNSET HILLS ROAD, SUITE 340, P.O. BOX 9204, RESTON, VA, 20190, US

(21) Appl. No.: 10/396,357

(22) Filed: Mar. 26, 2003

(30) Foreign Application Priority Data
Mar. 27, 2002 (JP) 2002-089655

(51) Int. Cl. G11C 29/00

(52) U.S. Cl. 365/201

(57) ABSTRACT

A test method of semiconductor memory devices is provided which is capable of effectively testing a data holding characteristic of semiconductor memory devices, such as a dynamic random access memory, in a short time. The test method includes a process of mounting test-specific memory cells each having a same configuration as each of memory cells and in which one electrode of a switching metal oxide semiconductor transistor is connected to each of bit lines and test-specific word lines being connected commonly to a gate electrode of a switching metal oxide semiconductor transistor, a step of writing high-level data to all memory cells, a step of writing low-level data to each of test-specific memory cells in which a gate electrode of a switching metal oxide semiconductor transistor is connected to each of test-specific word lines, a step of alternately setting each of the test-specific word lines at a selected level and at a non-selected level, and a step of reading data from each of memory cells.

### BACKGROUND OF THE INVENTION

1. Field of the Invention

The present invention relates to a semiconductor memory devices, a method for testing the same, and semiconductor devices and more particularly to the test method of the semiconductor memory devices to test data holding time of a semiconductor memory device such as a synchronous-type DRAM (Dynamic Random Access Memory) or a like operating in synchronization with a DRAM or an external clock, to semiconductor memory devices to which the above test method is able to be applied, and to the semiconductor device such as a CPU (Central Processing Unit) and/or an SOC (System On Chip) in which a system configured by connecting a plurality of input and output units or a like through a bus is embedded into one semiconductor chip to which the above test method is applied.

The present application claims priority of Japanese Patent Application No. 2002-089655 filed on Mar. 27, 2002, which is hereby incorporated by reference.

2. Description of the Related Art

A semiconductor memory device such as a DRAM (Dynamic Random Access Memory) or a synchronous-type DRAM (hereafter simply referred to as a “DRAM or a like”), as is known, is made up of a memory array in which memory cells each being constructed of a memory capacitor and a switching MOS (Metal Oxide Semiconductor) transistor are arranged in a matrix form. One bit of “H”-level data or “L”-level data is stored depending on whether an electric charge is accumulated in a memory capacitor. Data, that is, an electric charge being accumulated in the memory capacitor is held once, however, the electric charge is gradually reduced with time due to a leakage current existing slightly in the memory capacitor and is lost finally. Therefore, by turning on a switching MOS transistor every specified time to detect an electric charge being stored and being decreased and then by amplifying the detected electric charge using a sense amplifier, refresh has to be performed on a same memory capacitor to be again charged. A time interval between one refresh for each memory cell and another refresh is designated, for example, in the case of a 16-megabit DRAM or a like, to be 16 ms or less, data holding time is required to be more 16 ms even under the worst conditions.

Therefore, a manufacturer of a semiconductor memory device performs a data holding test to check whether the manufactured semiconductor memory device provides a predetermined data holding time. Various types of the data hold tests are available. Of them, a digit (bit) disturb hold test is described below. In the digit disturb hold test, out of a plurality of memory cells making up a memory cell array, data are written in all memory cells (hereafter being referred to as “cells to be noted”) in which a gate electrode of a switching MOS transistor of each of the memory cells is connected to each of word lines other than each of specified word lines on which a disturbing processing to be described later is performed and, by setting the above specified word lines at a selected level and at a non-selected level alternately a predetermined number of times (thereafter, this process being called “disturbing processing”) while the cells to be noted are holding data, an influence on contents stored in the cells to be noted is checked.

First, configurations of main components of a conventional DRAM are described by referring to FIG. 6 and FIG. 7. The DRAM of the example is a multi-bank type DRAM having a plurality of banks each being made up of a memory cell array and circuits being placed on its periphery, which chiefly includes banks 1₀ to 1ₙ (“n” is a natural number) and a row decoder 2. Each of the banks 1₀ to 1ₙ, though not shown, chiefly includes at least one memory cell, a plurality of sense amplifiers, and input/output buses. The row decoder 2 decodes a row address signal RAD fed from an outside and outputs a row selecting signal to put a word line corresponding to each of the banks 1₀ to 1ₙ into the selected state. Moreover, the DRAM of the example, in addition to the above components, though not shown, includes a column decoder to decode a column address signal fed from an outside and to output a column selecting signal to put a bit line corresponding to the banks 1₀ to 1ₙ into a selected state, an internal voltage generating circuit to generate an internal voltage to be fed to peripheral circuits, or a like and these components are formed on one semiconductor chip by using a known semiconductor manufacturing technology.

Next, configurations of main components of the bank 1₀ making up the DRAM shown in FIG. 6 are explained by referring to FIG. 7. In the bank 1₀ of the example, as shown in FIG. 7, memory cells 3 are arranged in a matrix form. Bit lines 4₀₁, 4₀₂, 4₁₁, 4₁₂, . . . are formed in such a manner as to be extend in a row direction with a specified distance apart from one another in a column direction and each of them is connected to one electrode of a switching MOS transistor (not shown) making up the corresponding memory cell 3. Moreover, another electrode of the switching MOS transistor (not shown) making up each of the memory cells 3 is connected to a corresponding memory capacitor (not shown). Each pair made up the bit lines 4₀₁ and 4₀₂, bit lines 4₁₁ and 4₁₂, . . . is connected to each of corresponding sense amplifiers 5₀, 5₁, . . . Each of the sense amplifiers 5₀, 5₁, detects data read from each of the memory cells 3 to each of the bit lines 4₀₁, 4₀₂, 4₁₁, 4₁₂, . . . and amplifies it. Each of word lines 6₀, 6₁, 6₂, . . . is formed in such a manner as to extend in a column direction with a specified distance apart from one another and also in a manner that each of the word lines 6₀, 6₁, 6₂, . . . and each of the bit lines 4₀₁, 4₀₂, 4₁₁, 4₁₂, . . . intersect at right angles. Each of word lines 6₀, 6₁, 6₂, . . . is connected to a gate electrode of a switching MOS transistor (not shown) making up each of the corresponding memory cells 3. Configurations of main components of other banks 1₁ to 1ₙ are almost the same as those of the above bank 1₀ and their descriptions are omitted accordingly.

Next, the digit disturb hold test to check a data holding characteristic in the DRAM having the above configurations is explained below.

(a) First, as shown in FIG. 8, “H” (high)-level data is written to all the memory cells 3 in the bank 1₀ In FIG. 8, the memory cells 3 expressed by being filled in with black show that they are maintained at a “H” (high) level.

(b) Then, as shown in FIG. 9, “L” (low) c level data is written to each of the memory cells 3 in which a gate electrode of a switching MOS transistor (not shown) is connected to the word line 6₀. In FIG. 9, the memory cells 3 expressed by being filled in with white show that they are maintained at a “L” (low) level.

(c) Next, data is held in a cell to be noted for a specified period of time (for example, 16 ms for a 16-megabit DRAM or a like) and during the specified period of time, by getting access to the word line 6₀ a plurality of times (that is, by doing alternate setting of a selected level or non-selected level), data is read from the memory cell 3 in which a gate electrode of a switching MOS transistor (not shown) is connected to the word line 6₀. Here, a number of times of getting the access depends on a frequency of a clock to be employed in the DRAM. For example, if the frequency of the clock is 100 MHz, since its period Tc is 10 ns, in order to meet specifications in which data hold time T_{DH} is designated to be 16 ms, the number of times of getting the access T_{ACS} is calculated to be 1.6 million from an equation (1):

T_{ACS}=T_{DH}/T_{c}=16×10⁻³/10×10⁻⁹=16×10⁵ (1)

By getting access to the word line 6₀, each of the memory cell 3 in which one electrode of a switching MOS transistor (not shown) is connected through a same bit contact (not shown) to bit lines 4₀₂, 4₁₂, . . . is disturbed and, in the memory cell 3 having a poor data holding characteristic, an electric charge being accumulated in a memory capacitor (not shown) leaks though a switching MOS transistor (not shown).

(d) Next, data is read all the memory cells 3 making up the bank 1 and each of the memory cells 3 from which “H”-level data was not read, that is, which has a poor data holding characteristic is judged to be unusable (to be failed).

(e) Then, again as shown in FIG. 8, “H”-level data is written in all the memory cells 3 in the bank 1₀.

(f) Next, “L”-level data is written to the memory 3 in which a gate electrode of a switching MOS transistor (not shown) is connected to the word line 6₁.

(g) Then, data is held in a cell to be noted for a specified period of time (for example, 16 ms for a 16-megabit DRAM or a like) and during the specified period of time, by getting access to the word line 6₁, a plurality of times, data is read from the memory cell 3 in which a gate electrode of a switching MOS transistor (not shown) is connected to the word line 6₁. The number of times of getting access is 1.6 million as in the above case. By getting access to the word line 6₁, the memory cell 3 in which one electrode of a switching MOS transistor (not shown) is connected through a same bit contact (not shown) to the bit lines 4₀₁, 4₁₁, . . . is disturbed and in the memory cell 3 having a poor data holding characteristic, an electric charge being accumulated in a memory capacitor (not shown) leaks through a switching MOS transistor (not shown).

(h) Next, data is read all the memory cells 3 in the bank 1₀ and each of the memory cells 3 from which “L”-level data was not read, that is, which has a poor data holding characteristic is judged to be unusable (to be failed).

(i) Then, again as shown in FIG. 8, “H”-level data is written in all the memory cells 3 in the bank 1₀.

(j) Next, “L”-level data is written in each of the memory cells 3 in which a gate electrode of a switching MOS transistor (not shown) is connected to the word line 6₂.

(k) Then, data is held in a cell to be noted for a specified period of time (for example, 16 ms for a 16-megabit DRAM or a like) and during the specified period of time, by getting access to the word line 6₂ a plurality of times, data is read from the memory cell 3 in which a gate electrode of a switching MOS transistor (not shown) is connected to the word line 6₂. The number of times of getting access is 1.6 million as in the above case. By getting access to the word line 6₂, each of the memory cells 3 in which one electrode of a switching MOS transistor (not shown) is connected through a same bit contact (not shown) to bit lines 4₀₁, 4₁₁, . . . is disturbed and in each of the memory cells 3 having a poor data holding characteristic, an electric charge being accumulated in a memory capacitor (not shown) leaks through a switching MOS transistor (not shown).

(l) Next, data is read all the memory cells 3 and each of the memory cells 3 from which “H”-level data was not read, that is, which has a poor data holding characteristic is judged to be unusable (to be failed).

Moreover, since a main purpose of the tests (i) to (l) is to test a data holding characteristic of each of the memory cells 3 in which a gate electrode of a switching MOS transistor (not shown) is connected to the word line 6₁, writing and reading of data may be performed only on each of the memory cells 3 in which a gate electrode of a switching MOS transistor (not shown) is connected to the word line 6₁.

(m) Then, again as shown in FIG. 8, “H”-level data is written in all the memory cells 3 making up the bank 1₀.

(n) Next, “L”-level data is written in each of the memory cells 3 in which a gate electrode of a switching MOS transistor (not shown) is connected to the word line 6₃.

(o) Then, data is held in a cell to be noted for a specified period of time (for example, 16 ms for a 16-megabit DRAM or a like) and during the specified period of time, by getting access to the word line 6₃ a plurality of times, data is read from each of the memory cells 3 in which a gate electrode of a switching MOS transistor (not shown) is connected to the word line 6₃. The number of times of getting access is 1.6 million as in the above case. By getting access to the word line 6₃, each of the memory cells 3 in which one electrode of a switching MOS transistor (not shown) is connected through a same bit contact (not shown) to bit lines 4₀₂, 4₁₂, . . . is disturbed and in each of the memory cells 3 having a poor data holding characteristic, an electric charge being accumulated in a memory capacitor (not shown) leaks through a switching MOS transistor (not shown).

(p) Next, data is read all the memory cells 3 and each of the memory cells 3 from which “H”-level data was not read, that is, which has a poor data holding characteristic is judged to be unusable (to be failed).

Moreover, since a main purpose of the tests (m) to (p) is to test a data holding characteristic of each of the memory cells 3 in which a gate electrode of a switching MOS transistor (not shown) is connected to the word line 6₀, writing and reading of data may be performed only on each of the memory cells 3 in which a gate electrode of a switching MOS transistor (not shown) is connected to the word line 6₀.

The same processes as those in (a) to (p) are performed on remaining (n−1) pieces of the banks. Next, the same processes as those in (a) to (p) are performed on n-pieces of the banks in the case where “L”-level data is written in all memory cells 3 making up one bank in the processes (a), (e), (i), and (m). In this case, in the processes (b), (f), (j), and (n), data to be written in each of the memory cells 3 in which a gate electrode of a switching MOS transistor (not shown) is connected to each of the word lines 6₀ to 6₃ becomes reverse to that in the above case, that is, not the “L”-level but the “H”-level data is written.

Here, required time Tc for the conventional digit disturb hold test described above is calculated. In the test method described above, the test is conducted by using the word lines 6₀ and 6₁ to disturb each of the memory cells 3 in which a gate electrode of a switching MOS transistor (not shown) is connected to other word line, the word line 6₂ to disturb each of the memory cells 3 in which a gate electrode of a switching MOS transistor (not shown) is connected to the word 6₁, and by using the word line 6₃to disturb each of the memory cells 3 in which a gate electrode of a switching MOS transistor (not shown) is connected to the word line 6₀, for one bank respectively. This processing is performed on n-pieces of the banks and further same processes as described above are performed also in the case where L-level data is written in each of the memory cells 3 making up one bank. Therefore, the required time Tc is given by a following equation (2):

Tc=4×2×T_{H}×n (2)

where “T_{H}” denotes time during which data has to be held in each of the memory cells 3.

As described above, in the conventional digit disturb hold test, since the word line 6₂ is used only to disturb each of the memory cells 3 in which a gate electrode of a switching MOS transistor (not shown) is connected to the word line 6₁ and the word line 6₃ is used only to disturb each of the memory cells 3 in which a gate electrode of a switching MOS transistor (not shown) is connected to the word line 6₀, efficiency of using the word lines is very low. Therefore, the conventional digit disturb hold test cannot be applied to a probe test (hereinafter referred to as a “genuine test”) to check electrical characteristics or a like of an DRAM or a like, a test or a like to select the DRAM to be conducted after the genuine test.

### SUMMARY OF THE INVENTION

In view of the above, it is an object of the present invention to provide a test method of semiconductor memory devices which is capable of effectively testing a data holding characteristic of a DRAM or a like in a short time, a semiconductor memory device such as a DRAM or a synchronous-type DRAM to which the above test method is applied and a semiconductor device such as an SOC or a like to which the above test method is applied.

According to a first aspect of the present invention, there is provided a test method of semiconductor memory devices each having a plurality of memory cells each being made up of a memory capacitor and a switching metal oxide semiconductor (MOS) transistor and being arranged in a matrix form, a plurality of word lines being formed so as to extend in a column direction with a specified distance apart from one another in a row direction and each being connected to a gate electrode of the switching MOS transistor, and a plurality of bit lines being formed so as to extend in the row direction with a specified distance apart from one another in the column direction and each being connected to one electrode of the switching MOS transistor, the test method including;

a process of providing the semiconductor memory device with one test-specific memory cell or a plurality of the test-specific memory cells each having a same configuration as each of the memory cells, in which one electrode of the switching MOS transistor is connected to each of the plurality of bit lines and with test-specific word lines being commonly connected to the gate electrode of the switching MOS transistor making up each of the test-specific memory cells:

a first step of writing first data to all of the plurality of memory cells;

a second step of writing second data to each of the test-specific memory cells;

a third step of alternately setting each of the test-specific word lines at a selected level and at a non-selected level specified times; and

a fourth step of reading data from the plurality of memory cells.

In the foregoing first aspect, a preferable mode is one wherein the semiconductor memory device has a plurality of banks being provided with the plurality of memory cells, the plurality of word lines, the plurality of bit lines, the test-specific memory cells, and the test-specific word lines, to which the test-specific word lines making up each of the banks are commonly connected.

Another preferable mode is one wherein, in the semiconductor memory device or in each of the banks, every pair made up of two bit lines out of the plurality of bit lines is connected to a memory amplifier and two sets each being made up of each of the test-specific memory cells and of each of the test-specific word lines are provided and the first to fourth steps are performed to each of the test-specific word lines.

Still another preferable mode is one wherein, when the semiconductor memory device is provided with a plurality of redundant memory cells being able to be replaced with each of the memory cells having defects and with redundant word lines being commonly connected to gate electrodes of the plurality of redundant memories, with neither the test-specific memory cells nor the test-specific word lines being provided, in the second step, the second data is written to the redundant memory cells and, in the third step, the redundant word lines are alternately set at a selected level and at a non-selected level specified times.

An additional preferable mode is one wherein, in the semiconductor memory device, every pair made up of two bit lines out of the plurality of bit lines is connected to a memory amplifier and at least two sets each being made up of each of the redundant memory cells and of each of the word lines are provided and the first to fourth steps are performed on each of the redundant word lines.

According to a second aspect of the present invention, there is provided a semiconductor memory device including:

a plurality of memory cells each being made up of a memory capacitor and a switching metal oxide semiconductor (MOS) transistor and being arranged in a matrix form;

a plurality of word lines being formed so as to extend in a column direction with a specified distance apart from one another in a row direction and each being connected to a gate electrode of the switching MOS transistor;

a plurality of bit lines being formed so as to extend in the row direction with a specified distance apart from one another in the column direction and each being connected to one electrode of the switching MOS transistor;

one test-specific memory cell or a plurality of the test-specific memory cells each having a same configuration as each of the memory cells in which one electrode of the switching MOS transistor is connected to each of the plurality of bit lines; and

test-specific word lines being commonly connected to the gate electrode of the switching MOS transistor making up each of the test-specific memory cells.

In the foregoing second aspect, a preferable mode is one that wherein includes a plurality of banks each having the plurality of memory cells, the plurality of word lines, the plurality of bit lines, the test-specific memory cells, and the test-specific word lines, to which the test-specific word lines making up each of the banks are commonly connected.

Another preferable mode is one wherein every pair made up of two bit lines out of the plurality of bit lines is connected to a memory amplifier and wherein two sets each being made up of each of the test-specific memory cells and of each of the test-specific word lines are provided and wherein one electrode of one set of the test-specific memory cells out of the two sets each being made up of each of the test-specific memory cells and of each of the test-specific word lines is connected to one bit line making up the pair made up of two bit lines and one electrode of each of the test-specific memory cells making up another set is connected to another bit line of a pair made up of the two bit lines.

According to a third aspect of the present invention, there is provided a semiconductor device provided with a semiconductor memory portion including:

a plurality of memory cells each being made up of a memory capacitor and a switching metal oxide semiconductor (MOS) transistor and being arranged in a matrix form;

a plurality of word lines being formed so as to extend in a column direction with a specified distance apart from one another in a row direction and each being connected to a gate electrode of the switching MOS transistor;

a plurality of bit lines being formed so as to extend in the row direction with a specified distance apart from one another in the column direction and each being connected to one electrode of the switching MOS transistor;

one test-specific memory cell or a plurality of the test-specific memory cells each having a same configuration as each of the memory cells in which one electrode of the switching MOS transistor is connected to each of the plurality of bit lines; and

test-specific word lines being commonly connected to the gate electrode of the switching MOS transistor making up each of the test-specific memory cells.

With the above configurations, the test method is performed on semiconductor memory devices each having a plurality of memory cells each being made up of a memory capacitor and a switching MOS transistor and being arranged in a matrix form, a plurality of word lines being formed so as to extend in a column direction with a specified distance apart from one another in a row direction and each being connected to a gate electrode of the switching MOS transistor, and a plurality of bit lines being formed so as to extend in the row direction with a specified distance apart from one another in the column direction and each being connected to one electrode of the switching MOS transistor, the test method including a process of further providing the semiconductor memory device with one test-specific memory cell or a plurality of test-specific memory cells each having same configurations as those of each of the above memory cells in which one electrode of the switching MOS transistor is connected to each of a plurality of bit lines and with test-specific word lines each being connected commonly to the gate electrode of the switching MOS transistor making up each of the test-specific memory cells, a first step of writing first data to each of the test-specific memory cells, a second step of writing second data to each of the test-specific memory cells, a third step of alternately setting each of the test-specific word lines at a selected level and at a non-selected level specified times and a fourth step of reading data from a plurality of memory cells and, therefore, it is possible to effectively test a data holding characteristic of a DRAM or a like in a short time.

Also, with another configuration, since the semiconductor memory devices includes a plurality of banks each having a plurality of memory cells, a plurality of word lines, a plurality of bit lines, test-specific memory cells, and test-specific word lines and since each of the test-specific word lines making up each of the banks is commonly connected, a data holding characteristic of a multi-bank type DRAM can be effectively tested in a short time.

Furthermore, with another configuration, in a case where the semiconductor memory devices have a plurality of redundant memory cells that can be replaced with defective memories and redundant word lines being connected commonly to gate electrodes of the plurality of redundant memory cells, without providing the test-specific memory cells and test-specific word lines and, in the second step, second data is written to each of the redundant memory cells and, in the third step, the redundant word lines are alternately set at a selected level and at a non-selected level specified times and, therefore, a data holding characteristic of a DRAM or a like can be effectively tested in a short time without causing increased chip areas.

### BRIEF DESCRIPTION OF THE DRAWINGS

The above and other objects, advantages, and features of the present invention will be more apparent from the following description taken in conjunction with the accompanying drawings in which:

FIG. 1 is a circuit diagram showing configurations of main components of a bank making up a DRAM to which a test method of a semiconductor memory device of an embodiment of the present invention is applied;

FIG. 2 is a schematic block diagram showing configurations of main components of a DRAM to which the test method of a semiconductor memory device of the embodiment of the present invention is applied;

FIG. 3 is a diagram explaining the test method illustrated in FIG. 2;

FIG. 4 is another diagram explaining the test method illustrated in FIG. 2;

FIG. 5 is still yet another diagram explaining the test method illustrated in FIG. 2;

FIG. 6 is a schematic block diagram showing an example of configurations of a conventional DRAM;

FIG. 7 is a schematic block diagram showing an example of configurations of a main component of a bank making up the conventional DRAM;

FIG. 8 is a diagram explaining a conventional digit disturb hold test; and

FIG. 9 is also a diagram explaining the conventional digit disturb hold test.

### DETAILED DESCRIPTION OF THE PREFERRED EMBODIMENTS

Best modes of carrying out the present invention will be described in further detail using various embodiments with reference to the accompanying drawings.

### EMBODIMENT

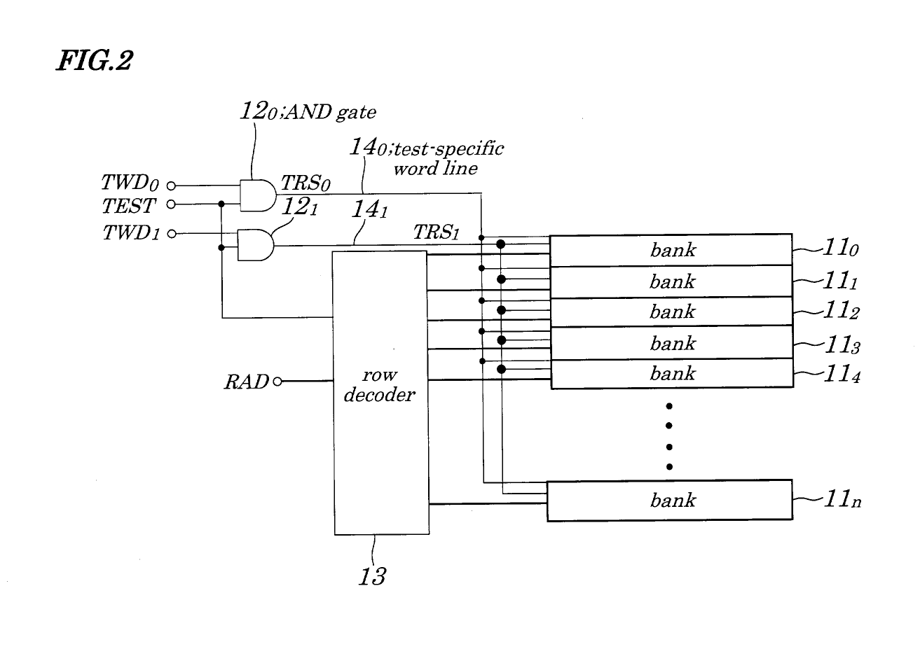

FIG. 2 is a schematic block diagram showing configurations of main components of a DRAM to which a test method of semiconductor memory device of an embodiment of the present invention is applied. The DRAM of the embodiment chiefly includes banks 11₀ to 11ₙ (“n” is a natural number), AND gates 12₀, and 12₁, a row decoder 13, and test-specific word lines 14₀ and 14₁. Each of the banks 11₀ to 11ₙ, although not shown is mainly made up of at least one memory cell array, a plurality of sense amplifiers, and an input/output bus. The AND gate 12₀ feeds a result obtained by ANDing a test signal TEST to be supplied to a first input terminal (not labeled) and a test-specific word signal TWD₀ to be supplied to a second input terminal (not labeled) in a form of a test-specific row selecting signal TRS₀ through the test-specific word line 14₀ to each of the banks 11₀ to 11ₙ. The AND gate 12₁ feeds a result obtained by ANDing the test signal TEST to be supplied to a first input terminal (not shown) and a test-specific word signal TWD₁ to be supplied to a second input terminal (not labeled) in a form of a test-specific row selecting signal TRS₁ through the test-specific word line 14₁ to each of the banks 11₀ to 11ₙ. The test signal TEST is used as a “L”-level signal when the DRAM of the embodiment is ordinarily used and as a “H”-level signal when various characteristics of the DRAM of the embodiment is tested.

The row decoder 13 decodes a row address signal RAD fed from an outside and outputs a row selecting signal to put a word line corresponding to each of the banks 11₀ to 11ₙ into a selected state. Also, the row decoder 13, when a “H”-level test signal TEST is fed, recognizes that the DRAM of the embodiment is set at a test mode. Each of the test-specific word lines 14₀ and 14₁ is commonly connected to each of the banks 11₀ to 11ₙ which is described later. Moreover, the DRAM of the embodiment is provided with a column decoder (not shown) to decode a column address to be fed from an outside and to output a column selecting signal (not shown) to put a bit line corresponding to each of the banks 11₀ to 11ₙ into a selected state, an internal voltage generating circuit (not shown) to generate an internal voltage to be fed to peripheral circuits, or a like, (not shown) in addition to components described above, which is formed on one semiconductor chip by using known semiconductor production technology.

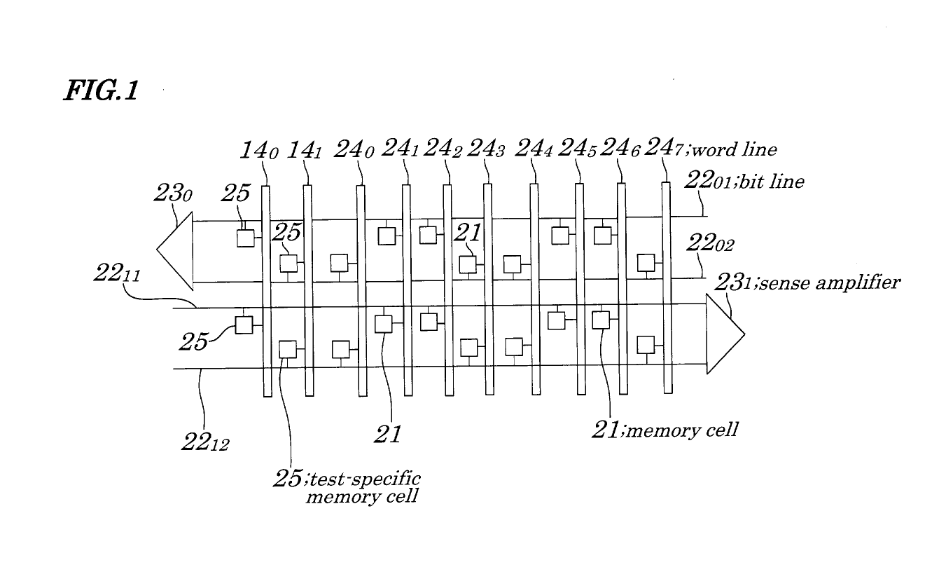

Next, configurations of main components of the bank 11₀ making up the DRAM shown in FIG. 2 are described by referring to FIG. 1. In the bank 11₀ of the embodiment, as shown in FIG. 1, memory cells 21 are arranged in a matrix form. Bit lines 22₀₁, 22₀₂, 22₁₁, 22₁₂, . . . are formed in such a manner as to extend in a row direction with a specified distance apart from one another in a column direction and each of the bit lines 22₀₁, 22₀₂, 22₁₁, 22₁₂, . . . is connected to one electrode of a switching MOS transistor (not shown) making up each of the corresponding memory cells 21. Another electrode of a switching MOS transistor (not shown) making up each of the memory cells 21 is connected to a corresponding memory capacitor (not shown). Moreover, a pair made up of bit lines 22₀₁ and 22₀₂, bit lines 22₁₁ and 22₁₂, . . . is connected to each of corresponding sense amplifiers 23₀, 23₁, . . . Each of the sense amplifiers 23₀, 23₁, . . . detects and amplifies data read from each of the memory cells 21 to each of the corresponding bit lines 22₀₁, 22₀₂, 22₁₁, 22₁₂, . . . Each of word lines 24₀, 24₁, 24₂, . . . is formed in such a manner as to extend in the column direction with a specified distance apart from one another in the row direction and also in a manner that each of the word lines 24₀, 24₁, 24₂, . . . and each of the bit lines 22₀₁, 22₀₂, 22₁₁, 22₁₂, . . . intersect at right angles. Each of word lines 24₀, 24₁, 24₂, . . . is connected to a gate electrode (not shown) of a switching MOS transistor (not shown) making up each of the corresponding memory cells 21.

Moreover, in the bank 11₀ of the embodiment, each of the above test-specific word lines 14₀ and 14₁, as shown in FIG. 1, is formed so as to extend in the column direction with a specified distance apart from one another in the row direction in a manner so as to be adjacent to each of the word lines 24₀, 24₁, 24₂, . . . and also in a manner that each of the test-specific word lines 14₀ and 14₁ and the bit lines 22₀₁, 22₀₂, 22₁₁, 22₁₂, . . . intersect at right angles. Moreover, in the bank 11₀ of the embodiment, as shown in FIG. 1, test-specific memory cells 25 are provided, each having same configurations of each of the memory cells 21 and in each of which one electrode of a switching MOS transistor (not shown) is connected to each of the bit lines 22₀₁, 22₀₂, 22₁₁, 22₁₂, . . . The gate electrode (not shown) of the switching MOS transistor (not shown) making up each of the test-specific memory cells 25 is connected to the corresponding test-specific word line 14₀ or 14₁. Also, another electrode (not shown) of the switching MOS transistor (not shown) making up each of the test-specific memory cells 25 is connected to a corresponding to a memory capacitor (not shown). Moreover, configurations of main components of other banks 11₁ to 11ₙ are same as those of the bank 11₀ and their descriptions are omitted accordingly.

Next, a method for testing a data holding characteristic of the DRAM having the above configurations is described.

(1) First, in order to set the DRAM of the embodiment at a test mode, a “H”-level test signal TEST is fed from an outside.

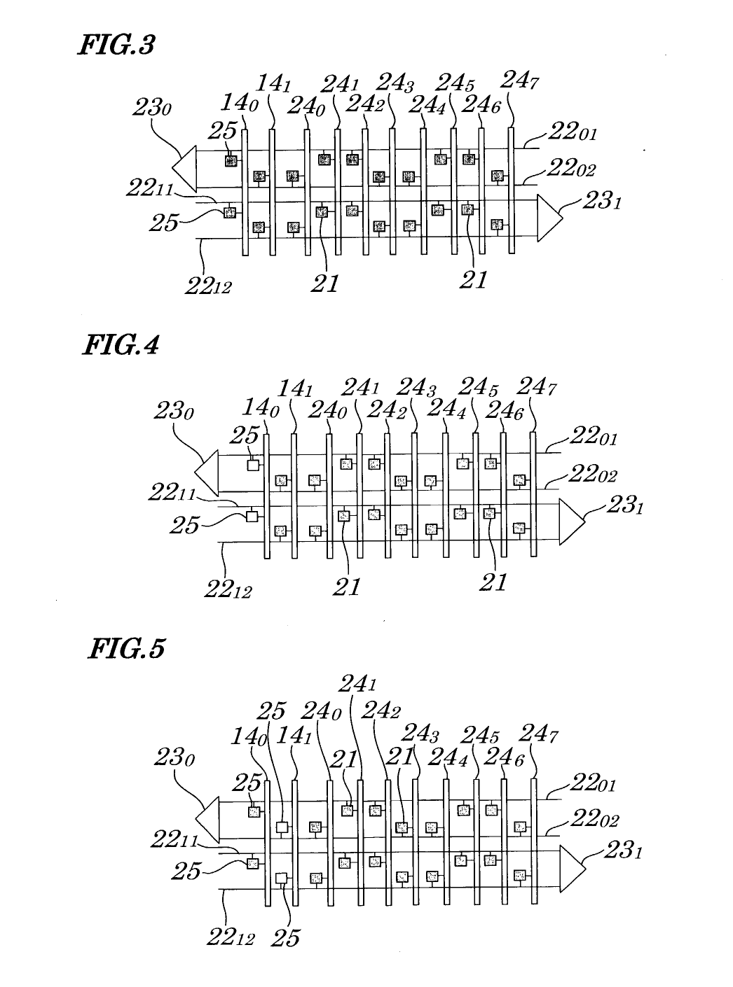

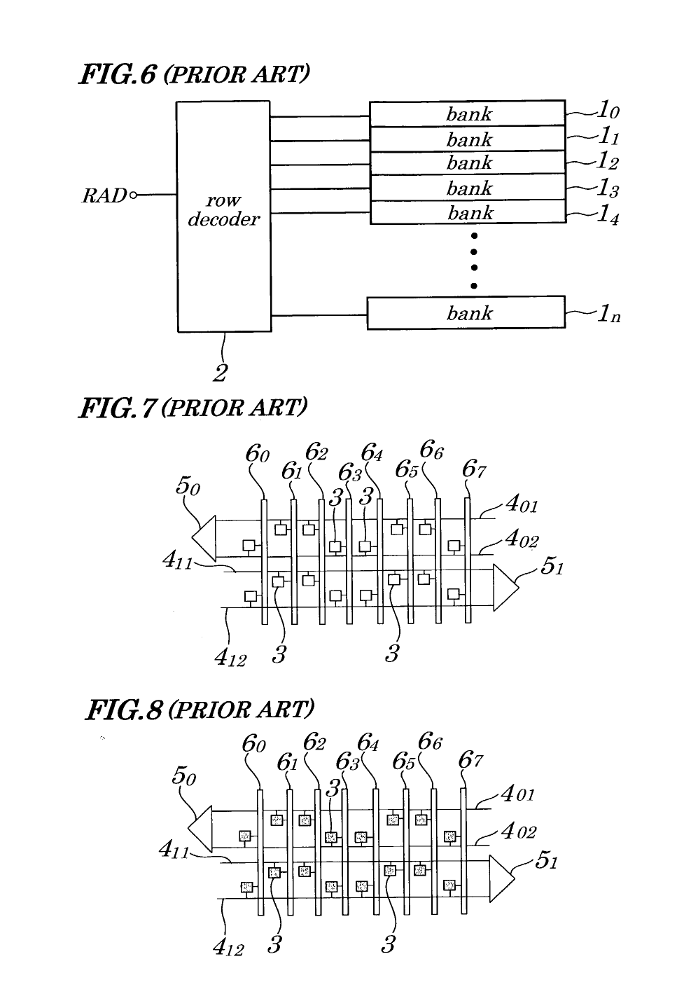

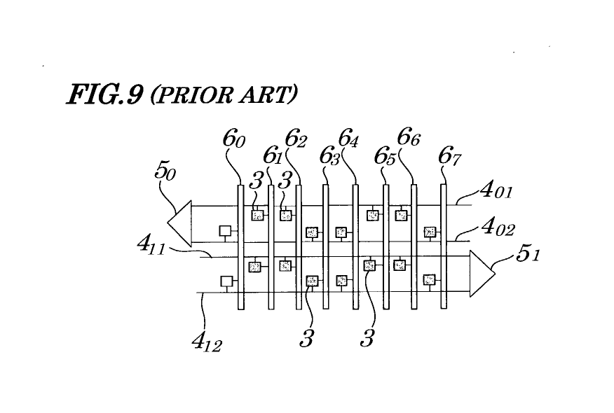

(2) Next, as shown in FIG. 3, “H”-level data is written in all the memory cells 21 making up each of the banks 11₀ to 11ₙ. In FIG. 3, the memory cells 21 expressed by being filled in with black show that they are maintained in a “H” -level state, as shown similarly in the following figures.

(3) Then, a “H”-level test-specific word signal TWD₀ is supplied from an outside (setting of a selection level). The AND gate 12₀ (FIG. 1) feeds a result obtained by ANDing a “H”-level test signal TEST to be supplied to a first input terminal and a “H”-level test-specific word signal TWD₀ to be supplied to a second input terminal in a form of a “H”-level test-specific row selecting signal TRS₀ through the test-specific word line 14₀ to each of the banks 11₀ to 11ₙ. At the same time, the bit lines 22₀₁, 22₁₁, . . . are set at a “L”-level. Therefore, in each of the banks 11₀ to 11ₙ, as shown in FIG. 4, a “L”-level data is written to each of the test-specific memory cells 25 in which the gate electrode (not shown) of a switching MOS transistor (not shown) is connected to the test-specific word line 14₀. In FIG. 4, the test-specific memory cells 25 expressed respectively by a hollow square shape show that they are maintained at a “L” level, as shown similarly in the following figures.

(4) Next, data is held in a cell to be tested for a specified period of time (for example, 16 ms for a 16-megabit DRAM or a like) and, during the specified period of time, by getting access to the test-specific word line 14₀ a plurality of times (for alternate setting of a selected level and a non-selected level), data is read from each of the test-specific memory cells 25 in which the gate electrode (not shown) of a switching MOS transistor (not shown) is connected to the test-specific word line 14₀. Here, the number of times of getting access is 1.6 million as in the above conventional case. By getting access to the test-specific word line 14₀, each of the memory cells 21 in which one electrode (not shown) of a switching MOS transistor (not shown) is connected through a same bit contact (not shown) to each of the bit lines 22₀₁, 22₁₁, is disturbed and in each of the memory cells 21 having a poor data holding characteristic, an electric charge being accumulated in a memory capacitor (not shown) leaks through a switching MOS transistor (not shown).

(5) Then, data is read from all the memory cells 21 and each of the memory cells 21 from which “H”-level data was not read, that is, which has a poor data holding characteristic is judged to be unusable (to be failed).

(6) Next, again as shown in FIG. 3, “H”-level data is written in all the memory cells 21 making up each of the bank 11₀ to 11ₙ.

(7) Then, a “H”-level test-specific word signal TWD₀ is fed from an outside. The AND gate 12₁ feeds a result obtained by ANDing a “H”-level test signal TEST to be supplied to the first input terminal (not shown) and a “H”-level test-specific word signal TWD₁ to be supplied to the second input terminal (not shown) in a form of a “H”-level test-specific row selecting signal TRS₁ through the test-specific word line 14₁₄ to each of the banks 11₀ to 11ₙ. At the same time, the bit lines 22₀₂, 22₁₂, . . . are set at a “L”-level. Therefore, in each of the banks 11₀ to 11ₙ, as shown in FIG. 5, a “L”-level data is written to each of the test-specific memory cell 25 in which the gate electrode (not shown) of a switching MOS transistor (not shown) is connected to the test-specific word line 14₁.

(8) Next, data is held in a cell to be tested for a specified period of time (for example, 16 ms for a 16-megabit DRAM or a like) and, during the specified period of time, by getting access to the test-specific word line 14₁ a plurality of times, data is read from each of the test-specific memory cells 25 in which the gate electrode (not shown) of a switching MOS transistor (not shown) is connected to the test-specific word line 14₁. Here, the number of times of getting access is 1.6 million as in the above step (4). By getting access to the test-specific word line 14₁, each of the memory cells 21 in which one electrode (not shown) of a switching MOS transistor (not shown) is connected through a same bit contact (not shown) to each of the bit lines 22₀₂, 22₁₂, . . . is disturbed and in the memory cell 21 having a poor data holding characteristic, an electric charge being accumulated in a memory capacitor (not shown) leaks through a switching MOS transistor (not shown).

(9) Then, data is read from all the memory cells 21 and each of the memory cells 21 from which “H”-level data was not read, that is, which has a poor data holding characteristic is judged to be unusable (to be failed).

Next, the same processes as those in (2) to (9) are performed in the case where “L”-level data is written in all memory cells 21 making up each of the banks 11₀ to 11ₙ in the processes (2) to (6). In this case, in the processes (3) and (7), data to be written in each of the memory cells 25 in which the gate electrode (not shown) of a switching MOS transistor (not shown) is connected to each of the test-specific word lines 14₀ to 14₁ becomes reverse to that in the above case, that is, not the “L”-level data but the “H”-level data is written.

Thus, according to configurations of the embodiment, since the test-specific word lines 14₀ and 14₁ are provided so that they can be commonly used in all the banks 11₀ to 11ₙ, the data holding characteristic of all memory cells 21 making up the DRAM can be tested effectively in a short time.

Here, required time (hereinafter called “required time T_{I} of the present invention”) in the case of using the configurations and test method of the embodiment can be obtained.

In the test method of the embodiment, since the test is conducted by using two pieces of the test-specific word lines 14₀ and 14₁ and same processes as described above are performed in a case where “L”-level data is written in all the memory cells 21 making up each of the banks 11₀ to 11ₙ, the required time of the present invention is given by a following equation (3):

T_{I}=2×2×T_{H} (3)

where “T_{H}” denotes time during which data has to be held in each of the memory cells 21.

As is apparent from the equations (2) and (3), even in the case where the DRAM is made up of one bank, the required time T_{I} of this embodiment is a half of the required time T_{C} in the conventional disturb hold test. In the case where the DRAM is made up of n-pieces of banks, the required time T_{I} can be reduced to about 1/2n of the required time T_{C} in the conventional disturb hold test.

It is apparent that the present invention is not limited to the above embodiments but may be changed and modified without departing from the scope and spirit of the invention. For example, in the above embodiment, a pair made up of the bit lines 22₀₁, 22₀₂, 22₁₁, 22₁₂, . . . is connected to each of the sense amplifiers 23₀, 23₁, . . . , however, the present invention is not limited to this. The present invention can be applied to a DRAM or a like in which one sense amplifier is connected to one bit line. In this case, only a single test-specific word line is used.

Moreover, in the above description, no reference is made as to which test that the DRAM undergoes the above test method of the embodiment is applied to. However, generally, it is preferable that the test method of the present invention is applied to one probe test (hereinafter called a “genuine test”) which is performed after another probe test (hereinafter called a “redundant test”) to check electrical characteristics or a like to replace a defective memory cell with a redundant memory cell has been finished. However, the present invention is not limited to this. The test method of the present invention may be applied not only to the genuine test but also to the redundant test and/or a test to select a DRAM to be performed after the genuine test has been completed.

Especially, in a case where the test method of the present invention is applied to a DRAM having redundant memory cells, by using redundant word lines being commonly connected to a plurality of redundant memory cells and gate electrodes of switching MOS transistors making up a plurality of redundant memory cells, instead of the test-specific memory cells 25 and the test-specific word lines 14₀ and 14₁, a data holding characteristic of the DRAM or a like can be tested effectively in a short time, without increasing a semiconductor memory device in chip size.

Furthermore, in the above embodiment, an example is provided in which the test method of the present invention is applied to testing of a single DRAM. However, the test method of the present invention may be applied to a single synchronous-type DRAM or an SOC (System On Chip) or an ASIC (Application Specific Integrated Circuit) in which DRAMs and/or the synchronous-type DRAMs are mounted in a mixed manner.

What is claimed is:

1. A test method of a semiconductor memory device each having a plurality of memory cells each being made up of a memory capacitor and a switching metal oxide semiconductor (MOS) transistor and being arranged in a matrix form, a plurality of word lines being formed so as to extend in a column direction with a specified distance apart from one another in a row direction and each being connected to a gate electrode of said switching MOS transistor, and a plurality of bit lines being formed so as to extend in said row direction with a specified distance apart from one another in said column direction and each being connected to one electrode of said switching MOS transistor, said test method comprising;
a process of providing said semiconductor memory device with one test-specific memory cell or a plurality of said test-specific memory cells each having a same configuration as each of said memory cells, in which one electrode of said switching MOS transistor is connected to each of said plurality of bit lines and with test-specific word lines being commonly connected to said gate electrode of said switching MOS transistor making up each of said test-specific memory cells:
a first step of writing first data to all of said plurality of memory cells;
a second step of writing second data to each of said test-specific memory cells;
a third step of alternately setting each of said test-specific word lines at a selected level and at anon-selected level specified times; and
a fourth step of reading data from said plurality of memory cells.

2. The test method of the semiconductor memory device according to claim 1, wherein said semiconductor memory device has a plurality of banks being provided with said plurality of memory cells, said plurality of word lines, said plurality of bit lines, said test-specific memory cells, and said test-specific word lines, to which said test-specific word lines making up each of said banks are commonly connected.

3. The test method of the semiconductor memory device according to claim 1, wherein, in said semiconductor memory device or in each of said banks, every pair made up of two bit lines out of said plurality of bit lines is connected to a memory amplifier and two sets each being made up of each of said test-specific memory cells and of each of said test-specific word lines are provided and said first to fourth steps are performed to each of said test-specific word lines.

4. The test method of the semiconductor memory device according to claim 1, wherein, when said semiconductor memory device is provided with a plurality of redundant memory cells being able to be replaced with each of said memory cells having defects and with redundant word lines being commonly connected to gate electrodes of said plurality of redundant memories, with neither said test-specific memory cells nor said test-specific word lines being provided, in said second step, said second data is written to said redundant memory cells and, in said third step, said redundant word lines are alternately set at a selected level and at a non-selected level specified times.

5. The test method of the semiconductor memory device according to claim 4, wherein, in said semiconductor memory device, every pair made up of two bit lines out of said plurality of bit lines is connected to a memory amplifier and at least two sets each being made up of each of said redundant memory cells and of each of said word lines are provided and said first to fourth steps are performed on each of said redundant word lines.

6. A semiconductor memory device comprising:
a plurality of memory cells each being made up of a memory capacitor and a switching metal oxide semiconductor (MOS) transistor and being arranged in a matrix form;
a plurality of word lines being formed so as to extend in a column direction with a specified distance apart from one another in a row direction and each being connected to a gate electrode of said switching MOS transistor;
a plurality of bit lines being formed so as to extend in said row direction with a specified distance apart from one another in said column direction and each being connected to one electrode of said switching MOS transistor;
one test-specific memory cell or a plurality of said test-specific memory cells each having a same configuration as each of said memory cells in which one electrode of said switching MOS transistor is connected to each of said plurality of bit lines; and
test-specific word lines being commonly connected to said gate electrode of said switching MOS transistor making up each of said test-specific memory cells.

7. The semiconductor memory device according to claim 6, comprising a plurality of banks each having said plurality of memory cells, said plurality of word lines, said plurality of bit lines, said test-specific memory cells, and said test-specific word lines, to which said test-specific word lines making up each of said banks are commonly connected.

8. The semiconductor memory device according to claim 6, wherein every pair made up of two bit lines out of said plurality of bit lines is connected to a memory amplifier and wherein two sets each being made up of each of said test-specific memory cells and of each of said test-specific word lines are provided and wherein one electrode of one set of said test-specific memory cells out of said two sets each being made up of each of said test-specific memory cells and of each of said test-specific word lines is connected to one bit line making up said pair made up of two bit lines and one electrode of each of said test-specific memory cells making up another set is connected to another bit line of a pair made up of said two bit lines.

9. A semiconductor device provided with a semiconductor memory portion comprising:
a plurality of memory cells each being made up of a memory capacitor and a switching metal oxide semiconductor (MOS) transistor and being arranged in a matrix form;
a plurality of word lines being formed so as to extend in a column direction with a specified distance apart from one another in a row direction and each being connected to a gate electrode of said switching MOS transistor;
a plurality of bit lines being formed so as to extend in said row direction with a specified distance apart from one another in said column direction and each being connected to one electrode of said switching MOS transistor;
one test-specific memory cell or a plurality of said test-specific memory cells each having a same configuration as each of said memory cells in which one electrode of said switching MOS transistor is connected to each of said plurality of bit lines; and
test-specific word lines being commonly connected to said gate electrode of said switching MOS transistor making up each of said test-specific memory cells.

10. A semiconductor device according to claim 9, comprising a plurality of banks each having said plurality of memory cells, said plurality of word lines, said plurality of bit lines, said test-specific memory cells, and said test-specific word lines, to which said test-specific word lines making up each of said banks are commonly connected.

11. The semiconductor memory device according to claim 9, wherein every pair made up of two bit lines out of said plurality of bit lines is connected to a memory amplifier and wherein two sets each being made up of each of said test-specific memory cells and of each of said test-specific word lines are provided and wherein one electrode of one set of said test-specific memory cells out of said two sets each being made up of each of said test-specific memory cells and of each of said test-specific word lines is connected to one bit line making up said pair made up of two bit lines and one electrode of each of said test-specific memory cells making up another set is connected to another bit line of a pair made up of said two bit lines.
